(19) United States
(12) Patent Application Publication
(10) Pub. No.: US 2024/0309506 A1
(43) Pub. Date: Sep. 19, 2024

(54) SUBSTRATE PROCESSING APPARATUS AND SUBSTRATE PROCESSING METHOD

(71) Applicant: WONIK IPS CO., LTD., Pyeongtaek-si Gyeonggi-do (KR)

(72) Inventors: Jae Jin HAN, Pyeongtaek-si Gyeonggi-do (KR); Kun Woo PARK, Pyeongtaek-si Gyeonggi-do (KR); Woo Young PARK, Pyeongtaek-si Gyeonggi-do (KR); Sung Hwan LEE, Pyeongtaek-si Gyeonggi-do (KR)

(73) Assignee: WONIK IPS CO., LTD., Pyeongtaek-si Gyeonggi-do (KR)

(21) Appl. No.: 18/499,943

(22) Filed: Nov. 1, 2023

(30) Foreign Application Priority Data
Mar. 14, 2023 (KR) 10-2023-0033438
Aug. 25, 2023 (KR) 10-2023-0111714

(51) Int. Cl. C23C 16/455; C23C 16/44; C23C 16/458; C23C 16/52

(52) U.S. Cl. CPC C23C 16/45548; C23C 16/4408; C23C 16/458; C23C 16/52

(57) ABSTRACT

Disclosed herein is a substrate processing apparatus including a process chamber having a reaction space formed therein, a substrate support installed in the reaction space to support a plurality of substrates, the substrate support comprising a susceptor plate, a plurality of vacuum holes formed in a top surface of the susceptor plate, and a vacuum line connecting the plurality of vacuum holes to an external pump, a gas injector comprising a plurality of gas injection units disposed radially to face the substrate support to inject process gas into the reaction space, and a controller configured to adjust a chucking force on the substrates according to a type of gas supplied through the gas injector.

### CROSS-REFERENCE TO RELATED APPLICATION

This application claims priority to and the benefit under 35 U.S.C. § 119(a) to Korean Patent Application Nos. 10-2023-0033438, filed on Mar. 14, 2023 and 10-2023-0111714, filed on Aug. 25, 2023, in the Korean Intellectual Property Office, the disclosure of which is incorporated herein by reference in its entirety.

### BACKGROUND

### 1. Field of the Invention

The present disclosure relates to an apparatus and method for processing a substrate, and more particularly, to a substrate processing apparatus and a substrate processing method using the same.

### 2. Description of the Related Art

In general, to manufacture semiconductor devices, display devices, or solar cells, various processes are performed by a substrate processing apparatus including a process chamber in a vacuum atmosphere. For example, a substrate may be loaded into the process chamber and processes such as depositing a thin film on the substrate or etching the thin film may be performed. The substrate may be supported by a substrate support assembly installed in the process chamber, and process gas may be injected onto the substrate through a gas injector installed facing the substrate support assembly.

In such a substrate processing apparatus, the thin film is deposited in a single process temperature when heterogeneous precursors with non-overlapping ALD windows are used. When a precursor is used that does not satisfy the ALD window at a single process temperature, a portion thereof is deposited in the chemical vapor deposition (CVD) region, resulting in a poor distribution of film thickness for the precursor. In order to stabilize the film thickness distribution, a technique has been employed to change the heater setting temperature during the ALD film deposition process.

However, when the heater setting temperature is changed during the process, it takes about 1 hour or more to stabilize the distribution after the change of the heater setting temperature due to the heat capacity depending on the size of the chamber. Thus, the process time is very long to satisfy the ALD window.

### SUMMARY OF THE DISCLOSURE

Therefore, the present disclosure has been made in view of the above problems, and it is an object of the present disclosure to provide a substrate processing apparatus and a substrate processing method using the same, which can shorten the process time when using heterogeneous precursors with non-overlapping ALD windows, and which provides a uniform thickness distribution of a thin film. However, this object is exemplary and is not intended to limit the scope of the present disclosure.

In accordance with an aspect of the present disclosure, the above and other objects can be accomplished by the provision of a substrate processing apparatus including a process chamber having a reaction space formed therein, a substrate support installed in the reaction space to support a plurality of substrates, the substrate support comprising a susceptor plate, a plurality of vacuum holes formed in a top surface of the susceptor plate, and a vacuum line connecting the plurality of vacuum holes to an external pump, a gas injector comprising a plurality of gas injection units disposed radially to face the substrate support to inject process gas into the reaction space, and a controller configured to adjust a chucking force on the substrates according to a type of gas supplied through the gas injector.

According to the substrate processing apparatus, the controller may adjust a temperature of the substrates by controlling the chucking force on the substrates by operating, in an On or Off state, a valve provided to regulate a degree of vacuum in the susceptor plate, according to the type of the gas supplied through the gas injector.

According to the substrate processing apparatus, before supplying a first gas through the gas injector, the controller may operate, in the On state, the valve provided to regulate the degree of vacuum in the susceptor plate.

According to the substrate processing apparatus, before supplying a second gas through the gas injector, the controller may operate, in the Off state, the valve provided to regulate the degree of vacuum in the susceptor plate.

According to the substrate processing apparatus, the controller may adjust a temperature of the substrates by controlling the chucking force on the substrates by regulating an amount of gas injected into the process chamber by operating a gas supply valve of the gas injector.

According to the substrate processing apparatus, the susceptor plate may include a plurality of gas supply holes.

According to the substrate processing apparatus, the controller may adjust a temperature of the substrates by controlling the chucking force on the substrates by supplying purge gas through the plurality of gas supply holes.

In accordance with another aspect of the present disclosure, there is provided a method of processing substrates using a substrate processing apparatus including: a process chamber having a reaction space formed therein; a substrate support installed in the reaction space to support a plurality of substrates, the substrate support comprising a susceptor plate, a plurality of vacuum holes formed in a top surface of the susceptor plate, and a vacuum line connecting the plurality of vacuum holes to an external pump; a gas injector comprising a plurality of gas injection units disposed radially to face the substrate support to inject process gas into the reaction space; and a controller configured to adjust a chucking force on the substrates according to a type of gas supplied through the gas injector. The method may include loading the substrates into the process chamber and seating the substrates on the substrate support, respectively; and forming a thin film on the substrates while controlling the chucking force on the substrates according to the type of gas injected into the reaction spaces.

According to the method, the forming of the thin film may include adjusting a temperature of the substrates by controlling the chucking force on the substrates by operating, in an On state, a valve provided to regulate a degree of vacuum in the susceptor plate while supplying purge gas, before supplying a first gas through the gas injector.

According to the method, the forming of the thin film may include adjusting a temperature of the substrates by controlling the chucking force on the substrates by operating, in an Off state, a valve provided to regulate a degree of vacuum in the susceptor plate while supplying purge gas, before supplying a second gas through the gas injector.

According to the method, the forming of the thin film may include adjusting a temperature of the substrates by controlling the chucking force on the substrates by regulating an amount of gas injected into the process chamber by operating, in an On or Off state, a valve provided to regulate a degree of vacuum in the susceptor plate and operating a gas supply valve of the gas injector while supplying purge gas, before supplying a third gas through the gas injector.

According to the method, the forming of the thin film may include adjusting a temperature of the substrates by controlling the chucking force on the substrates by regulating an amount of gas injected into the process chamber by operating, in an On or Off state, a valve provided to regulate a degree of vacuum in the susceptor plate while supplying purge gas through a plurality of gas supply holes provided in the susceptor plate, before supplying a third gas through the gas injector.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic cross-sectional view illustrating a substrate processing apparatus 200 according to one embodiment of the present disclosure;

FIG. 2 is a schematic perspective view illustrating a substrate support 230 disposed in the substrate processing apparatus 200 shown in FIG. 1;

FIGS. 3 and 4 are schematic diagrams illustrating a substrate processing method according to one embodiment of the present disclosure;

FIGS. 5 and 6 are schematic diagrams illustrating a substrate processing method according to a comparative example of the present disclosure;

FIG. 7 is a graph depicting a change of temperature of a substrate using the substrate processing method according to one embodiment of the present disclosure; and

FIG. 8 is a graph depicting a change of temperature of a substrate using the substrate processing method according to the comparative example of the present disclosure.

### DETAILED DESCRIPTION OF THE DISCLOSURE

Hereinafter, several preferred embodiments of the present disclosure will be described in detail with reference to the accompanying drawings.

The embodiments of the present disclosure are provided to provide a thorough understanding of the present disclosure to those skilled in the art. Various modifications may be made to the following embodiments, and the scope of the present disclosure is not limited to the following embodiments. Rather, these embodiments are provided to make the disclosure complete and to fully convey the ideas of the disclosure to those skilled in the art. In addition, the thickness or size of each layer in the drawings is exaggerated for ease of illustration and clarity.

As described below, a substrate processing apparatus 200 according to one embodiment of the present disclosure may be employed as a thin film deposition apparatus for forming a thin film on a substrate S. For example, the substrate processing apparatus 200 may be employed for a thin film deposition apparatus using atomic layer deposition (ALD). In some embodiments, the substrate processing apparatus 200 may be used for a thin film deposition apparatus that requires a high temperature process.

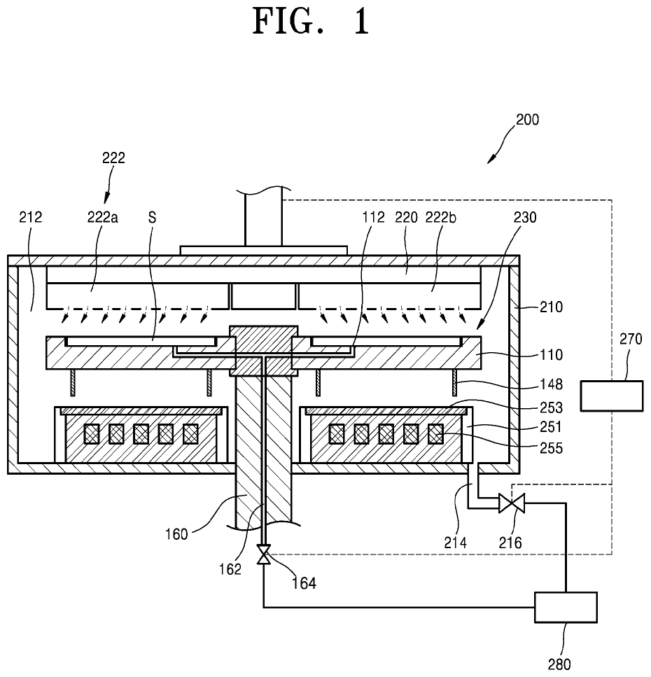

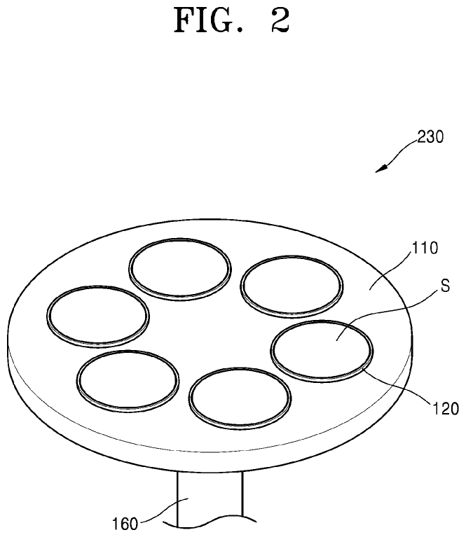

FIG. 1 is a schematic cross-sectional view illustrating the substrate processing apparatus 200 according to one embodiment of the present disclosure. FIG. 2 is a schematic perspective view illustrating a substrate support 230 disposed in the substrate processing apparatus 200 shown in FIG. 1.

Referring to FIGS. 1 and 2, the substrate processing apparatus 200 according to one embodiment of the present disclosure may include a process chamber 210, a gas injector 220, a substrate support 230, and a controller 270.

The process chamber 210 may include therein a reaction space 212 for processing the substrates S. For example, the process chamber 210 may be configured to be airtight and may be connected to an external pump 280 via at least one exhaust port 214 to discharge process gas from the reaction space 212 and to regulate the degree of vacuum within the reaction spaces. A valve 216 may be formed in at least a portion of the exhaust port 214 to control the degree of vacuum within the process chamber 210. The valve 216 may be configured in the form of, for example, a throttle valve to control the amount of air passing through the throttle body to control the degree of vacuum.

The process chamber 210 may be provided in various shapes, and may include, for example, a sidewall defining the reaction space 212 and a cover positioned on top of the sidewall. The process chamber 210 may further include an openable gate (not shown) in the sidewall portion for transferring the substrates S.

A gas injector 220 may be installed in the process chamber 210 to inject process gas into the reaction space 212. For example, the gas injector 220 may inject process gas supplied from outside of the process chamber 210 into the reaction space 212. More specifically, the gas injector 220 may be installed at the top of the process chamber 210 facing the susceptor plate 110 to inject process gas onto the substrates S seated on the substrate support 230.

In some embodiments, the gas injector 220 may include a plurality of gas injection units 222, and may include at least one inlet hole formed in a top layer or side portion to receive process gas from an external source, and a plurality of injection holes provided to inject process gas onto the substrates S. For example, the gas injector 220 may be formed in various shapes, such as a shower head shape or a nozzle shape.

More specifically, the gas injector 220 may include a plurality of gas injection units 222 arranged in an arc shape to allow the substrate S moving about the axis of rotation of the substrate support 230 in a circular orbit to pass sequentially through a plurality of process gas injection areas. The gas injection units 222 may each inject one a source gas, a reaction gas, and a purge gas as a process gas.

For example, the plurality of gas injection units 222 may include a source gas injection unit 222a, which is formed in a fan shape and has a plurality of gas injection holes formed in a gas injection surface to inject a source gas, and a reaction gas injection unit 222b, which is formed in a fan shape and has a plurality of gas injection holes formed in a gas injection surface to inject a reaction gas. Further, a purge gas injection unit (not shown) configured to inject a purge gas may be provided between the source gas injection unit 222a and the reaction gas injection unit 222b.

The substrate support 230 may be installed in the process chamber 210 to support the substrates S while facing the gas injector 220. For example, the substrate support 230 may be liftably and/or rotatably installed in the process chamber 210. The substrate support 230 may include the susceptor plate 110 and shafts 160. The substrate support 230 may include the substrate support 230.

In some embodiments, the substrate support 230 may be coupled to the process chamber 210 using a bellows structure (not shown) to allow the process chamber 210 to remain airtight during elevation and/or rotation of the shaft 160.

The susceptor plate 110 may include at least one seating groove 120 for seating the substrates S. For example, the seating grooves 120 may be provided in the form of pocket grooves in the susceptor plate 110. A plurality of seating grooves 120 may be formed in each of the susceptor plate 110. For example, a proper number of seating grooves 120 may be formed considering the size of the susceptor plate 110 and processing speed, without being limited to the number shown in FIG. 1.

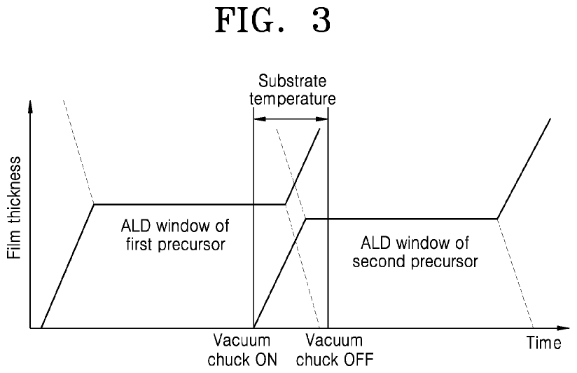

The substrate support 230 may be, for example, a vacuum chuck, and include a plurality of vacuum holes 112 formed on the top surface of the susceptor plate 110, and vacuum lines 162 connecting the vacuum holes 112 to an external pump 280. For example, the substrates S may be seated on the susceptor plate 110 and fixed according to the degree of vacuum regulated by means of the plurality of vacuum holes 112. Generally, the degree of vacuum is maintained at all times during the process. However, in the present disclosure, when two heterogeneous precursors with non-overlapping ALD windows are used, the process temperature of the substrates S may be adjusted by controlling the degree of vacuum depending on the type of process gas. In the following, methods of adjusting the process temperature of the substrates S will be described in detail with reference to FIGS. 3 to 6.

In some embodiments, the susceptor plate 110 may be provided with vacuum lines 162 connecting to the top surface of the susceptor plate 110 and to the seating grooves 120 for stable fixation of the substrates S, and the top surface seating grooves 120 of the susceptor plate 110 may have outlets (the plurality of vacuum holes 112) connected to the vacuum lines 162.

The shaft 160 may be coupled to the susceptor plate 110. For example, the shaft 160 may be coupled to a bottom or center of the susceptor plate 110 and extend downward. Further, the shaft 160 may rotate to allow the substrates S to revolve and may be liftable to move the substrates S up and down. For example, the shaft 160 may be coupled with a drive device (not shown). The shaft 160 may be rotated and/or moved up and down by the drive device. As the shaft 160 is rotated or moved up or down, the susceptor plate 110 may also be rotated or moved up or down.

A plurality of lift pins 148 may be connected through the susceptor plate 110. For example, the lift pins 148 may be supported at the lower end thereof and the positions of the susceptor plate 110 may be adjusted as the susceptor plate 110 are raised or lowered by the lift pins 148.

Below each of the susceptor plate 110 in the process chamber 210 may be disposed a heater 255 for heating the substrate S. For example, the heater 255 may include various heating sources such as a heating wire or a cartridge heater, and a plurality of heaters may be disposed. Further, below each of the susceptor plate 110 in the process chamber 210 may be disposed a housing body 251, which surrounds a side portion of the heater 255, and a quartz plate 253 supported on the housing body 251. For example, the housing body 251 may have a donut shape with a hollow center to allow the shaft 160 to extend through the center thereof. Further, the housing body 251 may be supported on the bottom surface of the process chamber 210.

Although not shown, the lift pins 148 may be supported on the quartz plate 253 as the susceptor plate 110 are lowered with the lowering of the shaft 160. The substrates S may be lifted onto the susceptor plate 110 while resting on the lift pins 148. The substrates S may then be removed from the lift pins 148 by a transfer robot (not shown).

Conversely, when loading the substrates S into the process chamber 210, the substrates S may be seated on the lift pins 148 by the transfer robot (not shown) with the lift pins 148 raised above the susceptor plate 110. The susceptor plate 110 may then be raised, and the substrates S may be seated on the susceptor plate 110.

The shaft 160 may have the vacuum line 162 formed in the susceptor plate 110. A valve 164 may be formed in at least a portion of the vacuum line 162 formed along the shaft 160, such that the chucking force on the substrates S may be controlled simply by controlling the valve 164 during the process. The valve 164 may be provided in the form of, for example, a throttle valve to control the amount of air passing through the throttle body to control the degree of vacuum. Alternatively, a separate throttle valve (not shown) may be connected between the vacuum line 162 and the valve 164 to control the chucking force on the substrates S.

The substrate processing apparatus 200 also includes a controller 270. The controller 270 may adjust the chucking force on the substrate S according to the type of gas supplied through the gas injector 220. Hereinafter, the operation of the controller 270 and the substrate processing method according to the operation will be described with reference to FIGS. 3 to 8.

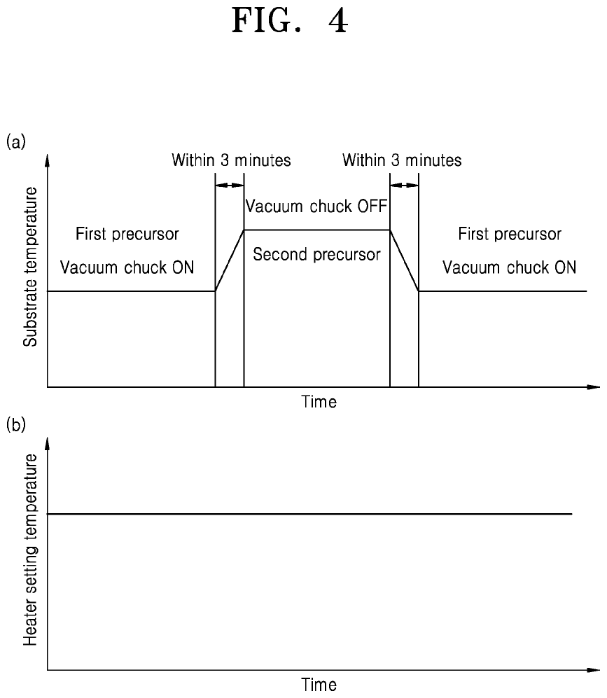

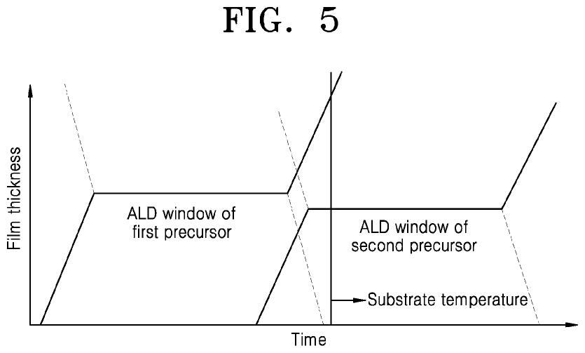

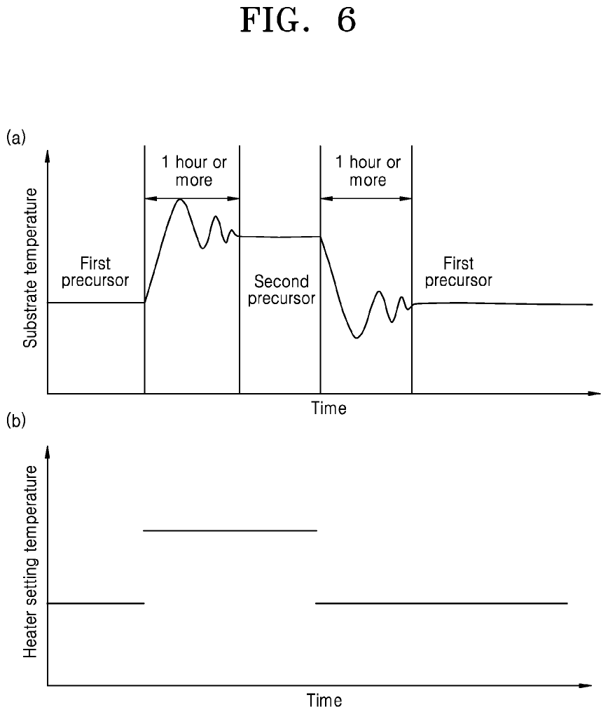

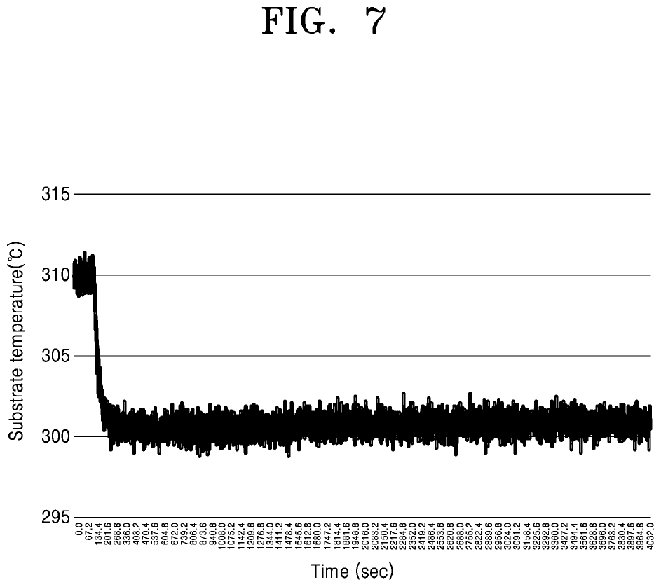

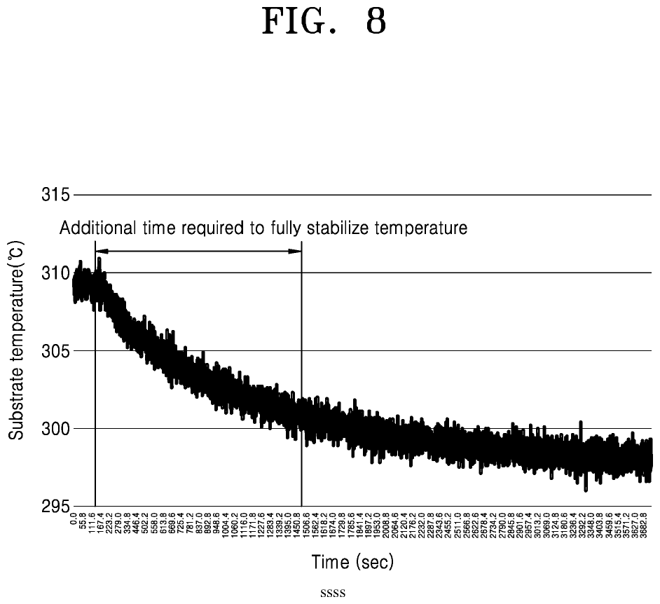

FIGS. 3 and 4 are schematic diagrams illustrating a substrate processing method according to one embodiment of the present disclosure, and FIGS. 5 and 6 are schematic diagrams illustrating a substrate processing method according to a comparative example of the present disclosure. FIG. 7 is a graph depicting a change of temperature of a substrate using the substrate processing method according to one embodiment of the present disclosure, and FIG. 8 is a graph depicting a change of temperature of a substrate using the substrate processing method according to the comparative example of the present disclosure.

Referring to FIG. 3, the controller 270 of the present disclosure may control the chucking force on the substrates S by operating the valve 164 for regulating the degree of vacuum in the substrate support 230 to an on or off state, depending on the type of process gas supplied through the gas injector 220. Specifically, prior to supplying a first precursor gas having a first ALD window through the gas injector 220, i.e., once the substrates S are seated on the substrate support 230, a first thin film may be deposited on the substrates S after operating the valve 164 for regulating the degree of vacuum in the susceptor plate 110 to an ON state.

Prior to supplying a second precursor (precursor) gas having a second ALD window different from the ALD window of first precursor gas, the valve 164 for regulating the degree of vacuum in the susceptor plate 110 may be operated to an OFF state. After stabilization is complete, a second thin film may be deposited on the substrate S on which the first thin film was deposited. When the valve 164 for regulating the degree of vacuum in the susceptor plate 110 is controlled to the OFF state, a purge gas may be supplied into the process chamber 210 through the gas injector 220.

As described above, by controlling the valve 164 provided to regulate the degree of vacuum in the vacuum chuck according to the types of process gas having different ALD windows, the effect of controlling the temperature of the substrates S may be achieved in a simple manner.

Referring to (a) and (b) of FIG. 4, without controlling the setting temperature of the heater 255 differently, the valve 164 for regulating the degree of vacuum in the susceptor plate 110 may be operated to an ON state before supplying the first precursor gas again after the second thin film is deposited. Then, the first thin film may be deposited on the second thin film. When the valve 164 for regulating the degree of vacuum in the susceptor plate 110 is controlled to the ON state, purge gas may be supplied into the process chamber 210 through the gas injector 220.

On the other hand, referring to FIG. 5, when the chucking force on the substrates S is not controlled, it is necessary to control the temperature of the substrates to be within the ALD window area by appropriately adjusting the setting temperature of the heater 255 according to the type of process gas. In this case, as shown in (a) and (b) of FIG. 6, the setting temperature stabilization time of the heater 255 taken to deposit each of the first precursor thin film and the second precursor thin film is more than 1 hour.

For example, referring to FIGS. 7 and 8, when supplying types of process gases whose ALD windows do not overlap, the setting temperature of the heater 255 may be kept constant simply by controlling the degree of vacuum of the vacuum chuck. Thus, the stabilization time may be shortened faster than in the conventional method (from more than 1 hour to less than 3 minutes). For example, heat from the heater 255 is not uniformly transferred to the substrate S due to vacuum holes 112 formed in the susceptor plate 110. When the setting temperature of the heater 255 is changed, the temperature stabilization time for the substrates S becomes prolonged. In this case, simply by controlling the degree of vacuum in the susceptor plate 110, the purge gas may be moved to the space between the lower surface of the substrates S and the susceptor plate 110, thereby shortening the time for the temperature stabilization of the substrates S by the convection effect.

As another example, in conjunction with controlling the degree of vacuum in the susceptor plate 110, the chucking force on the substrates S may be controlled by regulating the amount of purge gas injected into the process chamber 210 by operating the gas supply valve (not shown) of the gas injector 220. The purge gas may be supplied through the gas injector 220. The purge gas may also be supplied through a plurality of gas supply holes (not shown) separately formed in the top surface of the susceptor plate 110 in order to stabilize the substrate temperature by convection between the bottom surface of the substrates S and the top surface of the susceptor plate 110. In this case, the amount of purge gas may be appropriately regulated for the purpose of controlling the chucking force on the substrates S by connecting the vacuum line 162 to the substrates S in bypass form.

In addition to controlling the degree of vacuum in the susceptor plate 110, controlling the amount of purge gas supplied to the bottom surface of the substrate S or the top surface of the substrate S is also applicable to deposition methods using three or more precursor gases with different ALD windows. The amount of purge gas may be regulated using a gas controller 270 connected to the gas injector 220, for example, a separate gas control device such as an MFC.

For example, after sequentially depositing the first thin film and the second thin film on the substrates S using the first precursor gas and the second precursor gas, but before supplying the third gas through the gas injector 220, the valve 164 to regulate the degree of vacuum in the susceptor plate 110 may be operated to be set in an ON or OFF state while supplying the purge gas. At this time, the chucking force on the substrates S may be controlled by regulating the amount of the purge gas, and the third thin film may be deposited on the second thin film by supplying the third precursor gas after the temperature of the substrates S is stabilized. Based on the above-described methods, the controller 270 may control the chucking force on the substrates S by combining various methods depending on the type of precursor gas having a different ALD window area.

As is apparent from the above description, according to a substrate processing apparatus and a substrate processing method using the same according to one embodiment of the present disclosure configured as described above, a process time may be shortened and a thin film with a uniform thickness distribution may be formed when using heterogeneous precursors with non-overlapping ALD windows. It should be noted that the scope of the present disclosure is not limited by this effect.

Although the present disclosure has been described with reference to the embodiments shown in the drawings, these are exemplary only, and those of ordinary skill in the art will appreciate that various modifications and other equivalent embodiments are possible. Therefore, the true scope of the present disclosure should be defined by the appended claims of the present disclosure.

What is claimed is:

1. A substrate processing apparatus comprising:
a process chamber having a reaction space formed therein;
a substrate support installed in the reaction space to support a plurality of substrates, the substrate support comprising a susceptor plate, a plurality of vacuum holes formed in a top surface of the susceptor plate, and a vacuum line connecting the plurality of vacuum holes to an external pump;
a gas injector comprising a plurality of gas injection units disposed radially to face the substrate support to inject process gas into the reaction space; and
a controller configured to adjust a chucking force on the substrates according to a type of gas supplied through the gas injector.

2. The substrate processing apparatus of claim 1, wherein the controller adjusts a temperature of the substrates by controlling the chucking force on the substrates by operating, in an On or Off state, a valve provided to regulate a degree of vacuum in the susceptor plate, according to the type of the gas supplied through the gas injector.

3. The substrate processing apparatus of claim 2, wherein, before supplying a first gas through the gas injector, the controller operates, in the On state, the valve provided to regulate the degree of vacuum in the susceptor plate.

4. The substrate processing apparatus of claim 2, wherein, before supplying a second gas through the gas injector, the controller operates, in the Off state, the val ve provided to regulate the degree of vacuum in the susceptor plate.

5. The substrate processing apparatus of claim 1, wherein the controller adjusts a temperature of the substrates by controlling the chucking force on the substrates by regulating an amount of gas injected into the process chamber by operating a gas supply valve of the gas injector.

6. The substrate processing apparatus of claim 1, wherein the susceptor plate comprises a plurality of gas supply holes.

7. The substrate processing apparatus of claim 6, wherein the controller adjusts a temperature of the substrates by controlling the chucking force on the substrates by supplying purge gas through the plurality of gas supply holes.

8. A method of processing substrates using a substrate processing apparatus including: a process chamber having a reaction space formed therein; a substrate support installed in the reaction space to support a plurality of substrates, the substrate support comprising a susceptor plate, a plurality of vacuum holes formed in a top surface of the susceptor plate, and a vacuum line connecting the plurality of vacuum holes to an external pump; a gas injector comprising a plurality of gas injection units disposed radially to face the substrate support to inject process gas into the reaction space; and a controller configured to adjust a chucking force on the substrates according to a type of gas supplied through the gas injector, the method comprising:
loading the substrates into the process chamber and seating the substrates on the substrate support, respectively; and
forming a thin film on the substrates while controlling the chucking force on the substrates according to the type of gas injected into the reaction spaces.

9. The method of claim 8, wherein the forming of the thin film comprises:
adjusting a temperature of the substrates by controlling the chucking force on the substrates by operating, in an On state, a valve provided to regulate a degree of vacuum in the susceptor plate while supplying purge gas, before supplying a first gas through the gas injector.

10. The method of claim 8, wherein the forming of the thin film comprises:
adjusting a temperature of the substrates by controlling the chucking force on the substrates by operating, in an Off state, a valve provided to regulate a degree of vacuum in the susceptor plate while supplying purge gas, before supplying a second gas through the gas injector.

11. The method of claim 8, wherein the forming of the thin film comprises:
adjusting a temperature of the substrates by controlling the chucking force on the substrates by regulating an amount of gas injected into the process chamber by operating, in an On or Off state, a valve provided to regulate a degree of vacuum in the susceptor plate and operating a gas supply valve of the gas injector while supplying purge gas, before supplying a third gas through the gas injector.

12. The method of claim 8, wherein the forming of the thin film comprises: adjusting a temperature of the substrates by controlling the chucking force on the substrates by regulating an amount of gas injected into the process chamber by operating, in an On or Off state, a valve provided to regulate a degree of vacuum in the susceptor plate while supplying purge gas through a plurality of gas supply holes provided in the susceptor plate, before supplying a third gas through the gas injector.
